(19) United States
(12) Patent Application Publication
(10) Pub. No.: US 2024/0269579 A1
(43) Pub. Date: Aug. 15, 2024

(54) SAMPLE CELL, LOADING STATION, MEASURING DEVICE, METHODS FOR EXAMINING AND FOR PRODUCING A FLAT CRYSTAL, USE OF A SAMPLE CELL

(71) Applicant: Deutsches Elektronen-Synchrotron DESY, Hamburg (DE)

(72) Inventors: Alke MEENTS, Hamburg (DE); Sebastian GUENTHER, Hamburg (DE); Miriam BARTHELMESS, Hamburg (DE)

(73) Assignee: Deutsches Elektronen-Synchrotron DESY, Hamburg (DE)

(21) Appl. No.: 18/645,142

(22) Filed: Apr. 24, 2024

Related U.S. Application Data
(62) Division of application No. 17/894,313, filed on Aug. 24, 2022.

(30) Foreign Application Priority Data
Aug. 24, 2021 (EP) 21 192 887.4

(51) Int. Cl. B01D 9/00; G01N 1/28; G01N 23/20025

(52) U.S. Cl. CPC B01D 9/0036; G01N 1/28; G01N 23/20025

(57) ABSTRACT

A sample cell including a sample space, restricted on its first side by a first inner side of a first membrane and on its second side by a second inner side of a second membrane. A spacer is arranged between the first and the second inner sides to establish a distance between the membranes. A first retaining element is arranged on a first outer side, facing away from the sample space, of the first membrane and a second retaining element is arranged on a second outer side, which faces away from the sample space, of the second membrane, the first and second retaining elements together form a retaining structure. The first and second retaining elements each have a plurality of apertures aligned with each other in a direction transverse to the flat sides, to form a plurality of examination windows, in which the outer sides of the membranes are exposed.

### CROSS-REFERENCE TO RELATED APPLICATION

The present application is a Divisional Application of U.S. patent application Ser. No. 17/894,313, filed on Aug. 24, 2022, which is based upon and claims the benefit of priority from EP 21 192 887.4 filed on Aug. 24, 2021, the entire contents of which is incorporated herein by reference.

### BACKGROUND

### Field

The present disclosure relates to a sample cell, comprising a flat sample space, a loading station for receiving such a sample cell, and a measuring device for examining a sample which is present in the sample space of such a sample cell. The present disclosure further relates to a method for examining and a method for producing a flat crystal. The present disclosure also relates to the use of a sample cell.

### Prior Art

To examine samples by electron diffraction, it is necessary to provide very thin samples. The maximum thickness in the beam direction depends on the energy of the electrons used for the examination. Due to the interaction of the electrons with the material of the sample, it is also desirable to use samples for the examination that have the largest possible surface area laterally, meaning transversely to a beam direction. On the one hand, a strong diffraction signal can be obtained and, at the same time, possible radiation damage can be reduced by distributing the dose of radiation over a larger volume. Electron diffraction is especially suitable for the examination of crystals, in particular monocrystals. For this purpose, thin and at the same time laterally extensive crystals are particularly suitable.

An example of a commercially available system which is provided for examining liquids by electron diffraction in a transmission electron microscope (TEM) is offered by the company Norcada under the designation “Liquid Cell.” This system is designed for use with a sample holder, designed especially for this purpose, of a transmission electron microscope. It consists of two individual plates which act as a base and cover plate of the system and which are adapted in size and shape to the special TEM sample holder. A recess is provided centrally in the plates, into which recess a liquid can be introduced. If two such plates are placed onto each other, a cavity is formed which is sealed along the circumference by an O-ring lying between the plates. The TEM sample holder must exert pressure on the base and cover plates for this purpose. Such a sample cell is therefore only to be used in conjunction with the corresponding TEM sample holder and cannot be removed from it. This makes handling the samples laborious and relatively complicated.

### SUMMARY

An object is to provide a sample cell with a flat sample space, a loading station for receiving such a sample cell, a measuring device for examining a sample which is present in the sample space of the sample cell, a method for examining and a method for producing a flat crystal, and the use of such a sample cell, wherein the possibility should be created of providing a flat sample, such as a flat crystal, in the sample space for examination with simplified handling.

Such object can be solved by a sample cell, comprising at least one flat sample space, which is restricted on its first large flat side by a first inner side of a first membrane and on its second large flat side by a second inner side of a second membrane, wherein a spacer is arranged between the first and the second inner sides, which spacer establishes a distance between the two membranes, and wherein a first retaining element is arranged on a first outer side, which faces away from the sample space, of the first membrane and a second retaining element is arranged on a second outer side, which faces away from the sample space, of the second membrane, and the first and second retaining elements together form a retaining structure, wherein the first and second retaining elements each have a plurality of apertures which are arranged to align with each other in a direction transverse to the flat sides, so that a plurality of examination windows result, in which the outer sides of the membranes are exposed.

The sample cell can be suitable for receiving a liquid or also a suspension. The suspension can comprise, for example, small crystals (microcrystallites). The sample cell can be configured to receive a crystallizable sample solution. The flat sample space serves, according to this embodiment, as a flat reservoir for the crystallizable sample solution. From the crystallizable sample solution, a crystal, which is a polycrystal, such as a monocrystal, forms within the flat sample space.

The sample cell can comprise at least one sample space, which means that the sample cell can comprise a single or also multiple sample spaces. If the sample cell comprises multiple sample spaces, they can also be loaded with different samples. As already explained, these samples can in turn be, for example, one or more liquids, suspensions, or also crystallizable liquids.

The spacer, which defines the distance between the two membranes, can be built from multiple spacing elements, which can be arranged at various positions within the flat sample space, which can consider the mechanical stability of the sample cell, and extend between the inner sides of the membranes lying opposite each other. The apertures present in the first and second retaining elements can also be arranged to align with each other in a direction which runs at least approximately perpendicular to the planes in which the flat sides of the sample space extend.

With the sample cell, measurements by electromagnetic radiation can be performed on the sample present in the sample space. For example, the sample cell can be suitable for examining the sample by X-rays or also by electron diffraction. This means that X-ray measurements and/or measurements by electron diffraction can be performed on a sample, such as a crystal, or a monocrystal, present in the flat sample space. With regard to performing the electron diffraction measurements, the sample space can be flat, meaning has a low thickness in the beam direction. The sample present in the sample space can thus be irradiated well. To ensure that the sample can be irradiated well, the thickness of the sample, meaning the dimension of the sample in the beam direction, can be adapted to the wavelength or energy, such as the electron energy, used for the measurement. Due to the laterally large extent of the sample space, it is also possible to obtain a strong diffraction signal, wherein, at the same time, possible radiation damage can be reduced by the distribution of the dose over a larger sample volume. This can be important for the examination of samples which consist of organic crystals and are therefore particularly sensitive to radiation damage. This may be important in the case of measurements at room temperature, since in this case considerably stronger radiation damage occurs than in the case of measurements at low temperatures.

In addition, time-resolved measurements, for example on accelerator-based measurement apparatuses, such as electron diffraction apparatuses, can be performed. Time-resolved measurements require high beam intensities, which, as already explained, can be distributed over a large sample volume.

Another aspect that must be considered in the case of electron diffraction is the fact that the electron beam can only be focused with high loss of beam quality or intensity on a small beam cross-section of a few micrometers due to the reciprocal repulsion of the electrons. Therefore, electron diffractometry can be provided for laterally large samples, such as crystals. In this case, the lateral extent of the sample can correspond at least to the achievable minimum beam cross-section. In other words, the sample cell is suitable for electron diffractometry.

However, it is not only important to provide samples, such as crystals, whose extent is as large as possible laterally, meaning transversely to the beam direction, and is low in the beam direction. The sample substrate, meaning in this case the sample cell, can also contribute where possible to enabling a strong diffraction signal without a base that is too large and influences and therefore disrupts the measurement value. For this purpose, the sample cell can have examination windows, in which the sample space is delimited from the surroundings only by the membranes present on both sides. In other words, the retaining structure can have only a minimal influence on the achievable measurement signal in these regions.

The sample cell not only meets the requirements to perform measurements in high quality, it can also be very easy to handle. This can be achieved in that the entire sample cell can be configured as a single integral component. For example, it is not necessary to assemble it from multiple individual parts when loading the sample cell. It is also not necessary during the measurement to use the sample cell in a specially provided holder. According to another embodiment, the first condition can be met in that the spacer can be dimensioned such that the inner sides of the membranes have such a distance to each other that sample liquid can be absorbed into the sample space by capillary forces. According to another embodiment, the second condition can be met in that the retaining structure can be dimensioned such that the sample cell is inherently stable in its entirety. The latter can qualify the sample cell for fully or partially automated measurements. For example, it can be possible to handle the sample cell without issue using a robot. The sample cell can also be suitable for applications in which it is used as a liquid cell. For this purpose, the flat sample space can be filled with the liquid to be examined or a suspension.

According to an embodiment, the sample cell can be enhanced in that the first inner side of the first membrane is connected to the spacer, the first outer side of the first membrane is connected to the first retaining element, the second inner side of the second membrane is connected to the spacer, and the second outer side of the second membrane is connected to the second retaining element in a firmly bonded manner, such as being vacuum-tight.

The firmly bonded connection between the mentioned components takes place, for example, without auxiliary substances, i.e., the components can be connected to each other directly in a firmly bonded manner, without using auxiliary substances, such as a suitable adhesive or the like for this purpose. The auxiliary substance-free, firmly bonded connection can be realized, for example, in that the components to be connected to each other are pressed together by the application of suitable mechanical pressure. In this case, the components can also be connected to each other with the action of heat supporting the joining process. For example, a firmly bonded connection can be achieved by interdiffusions of the involved materials. However, it is also provided that the aforementioned components can be connected to each other in a firmly bonded manner using at least one auxiliary substance. For example, the components can be connected to each other using a suitable adhesive.

Due to the firmly bonded connection, the sample cell can be configured such that it is vacuum-tight. In other words, the firmly bonded connections of the individual components can be configured such that the required vacuum tightness is achieved. By configuring the sample cell to be vacuum-tight, it can be qualified for use in connection with electron diffraction measurements, which are typically performed under vacuum conditions. At the same time, in the sample space of the sample cell, sample materials can be examined that cannot be exposed to vacuum conditions, for example organic samples, such as samples that are present or must be present in a moist environment.

According to another embodiment, the sample cell can also comprise a sealing element, which extends between the first inner side of the first membrane and the second inner side of the second membrane in an edge region and seals off the sample space from an outer space, wherein the sealing element leaves at least one access opening free, through which the at least one sample space can be filled.

The sealing element can also be configured as a part of the spacer. The sealing element can be connected in a firmly bonded manner, such as being vacuum-tight, to the first inner side of the first membrane and to the second inner side of the second membrane. Furthermore, the at least one access opening can be closed in a firmly bonded manner, such as being vacuum-tight.

The access opening can be closed, for example, by a suitable adhesive. Then the sample cell can be suitable for vacuum applications. For applications under atmospheric pressure and with real-time measurement, the completely vacuum-tight sealing of the sample cell may be dispensed with. This can accelerate the entire measuring process, which includes the preparation of the sample.

The dimensions of the flat sample space, such as the thickness of the flat sample space determined by the spacer, can be selected so that a sample solution or suspension is sucked into the sample space by capillary forces as soon as the at least one access opening of the sample cell is in fluid contact with the sample solution or suspension. For this purpose, for example, the sample cell can be submerged into a sample solution or suspension until the at least one access opening is below a liquid level of the liquid. In this context, the sample cell, in contrast to conventional sample cells, is inherently stable, i.e., can be used, transported, and also stored without a specially provided holder.

The sample cell known from the prior art from the manufacturer Norcada is built from two individual separate plates, of which one serves as a base and another serves as a cover. Along with the sealing ring lying between them, these two plates must be clamped in a special holder which then must also be used for the measurement. With such a system, it is thus not possible to prepare multiple samples simultaneously for a subsequent measurement unless the large financial outlay of using a separate holder for each sample has been made. If a crystallization of a crystallizable sample solution is to be performed in such a sample cell, the system proves to be conceivably unsuitable for the reasons mentioned above. The sample cell provided herein eliminates these technical and economic disadvantages present in the prior art.

The sample cell comprises a first holder and a second holder, each of which are built from a plurality of webs. These webs are arranged, for example, in a regular grid. The apertures of the retaining element are located between adjacent webs. A first and a second retaining element can be provided as a retaining structure, which can have an at least approximately identical structure. It is thus possible to arrange the apertures present in the retaining elements to align with each other with little effort. The retaining elements can have a regular structure, which is configured, for example, such that the apertures present in the retaining element are arranged in a grid. For example, the apertures are arranged in two grid directions that are at least approximately perpendicular to each other, for example in a square grid. Thus, the individual examination windows can be approached during a fully or partially automated measurement with little effort. For example, a sample table used for the measurement can move the sample cell in a grid with a constant step size.

According to another embodiment, the spacer, viewed in a direction transverse to the large flat sides, can have a constant material thickness so that the inner sides of the membranes are arranged at least approximately plane-parallel to each other. The examination of a sample with a constant sample thickness provides that the measurements performed in the individual examination windows can be easily compared to each other.

According to another embodiment, the sample cell can be enhanced in that it can have at least one sample space having an aspect ratio between a lateral extent, measured in a direction at least approximately parallel to the large flat sides, and thickness, measured in a direction at least approximately perpendicular to the large flat sides, of at least 10 to 1 or greater. The extent of the at least one sample space is thus, considered in a direction at least approximately parallel to the large flat sides, at least ten times as large as the extent of the at least one sample space in a direction perpendicular thereto. The at least one sample space can also have a considerably larger aspect ratio, for example of 20 to 1, further, for example, of 100 to 1 or even 1000 to 1. The previously mentioned aspect ratios can have particular utility in practice. A sample is provided which has a lateral extent that is large enough to provide a sufficient number of measuring points at a given sample thickness.

According to another embodiment, the sample cell can have a sample space, the lateral extents of which, measured in a direction at least approximately parallel to the large flat sides, can be between 100 μm and 100 mm and the sample space of which has a thickness, measured in a direction at least approximately perpendicular to the large flat sides, between 1 nm and 10 μm. Such a sample cell with the mentioned dimensions can have particular utility in practice for application in electron diffraction.

The thickness of the at least one sample space can be dependent on the energy of the electromagnetic radiation used for the measurement or the electron energy. According to further embodiments, the sample cell can be configured such that its sample space has a thickness of less than or equal to 800 nm. Such a sample cell can have particular utility suitable for measurement by an electron beam which can have an energy of at least approximately 3 MeV. The sample cell can have a sample space with a thickness between 500 nm and 1 μm. Such a sample cell can have particular utility suitable for measurements in which the electron energy is between 2 and 3 MeV. According to another embodiment, the sample space of the sample cell can have a thickness of less than or equal to 300 nm. Such a sample cell can have particular utility suited for electron diffraction measurements which can be performed at an energy of 300 keV.

In order to set the thickness of the sample space accordingly, the sample cell according to the aforementioned embodiments can have a spacer, which is, for example, at least approximately 800 nm high. According to the further mentioned embodiments, the spacer can be configured such that it has a height between 500 nm and 1 μm. In order to realize a substantially flat sample space, it is provided that, according to the further embodiment, the spacer can have a height of less than or equal to 300 nm.

According to further embodiments, the material thickness or height of the spacer can be between 100 nm and 1 μm, or below 300 nm or below 500 nm. Further, it is provided that the spacer can have a material thickness between 500 nm and 1 μm.

The spacer can be produced, for example, from a metal, such as from gold. According to another embodiment, a photoresist or a suitable polymer can be used as the spacer.

According to another embodiment, the retaining structure of the sample cell can be configured with a material thickness of less than or equal to 200 μm. For example, the material thickness of the retaining structure can be between 100 μm and 200 μm. In this context, the material thickness of each of the individual retaining elements, meaning of the first or of the second retaining element which together form the retaining structure, can be considered. The retaining elements can be produced, for example, from silicon. The retaining elements can be structure by methods and techniques as they are technically generally known and typical for the structuring of silicon. A typical method for the structuring of silicon is, for example, photolithography.

According to further embodiments, the membrane of the sample cell can be produced from silicon nitride (SiN), from graphene, from amorphous carbon, from silicon (Si), from boron nitride (BN), or a polymer. The membrane can have a material thickness in the range between 1 nm and 100 nm. For silicon nitride (SiN), a material thickness between 30 nm and 100 nm can have particular utility. A membrane made of the aforementioned materials and with the aforementioned material thickness can be largely electron-transparent, which can have particular utility for the use of the sample cell in electron diffractometry.

According to another embodiment, the examination windows can have a lateral dimension that is between 10 μm and 200 μm. This dimension can be measured in a direction at least approximately parallel to the large flat sides. A sample cell with such examination windows can have articular utility suitable for electron diffraction because, due to the reciprocal repulsion of the electrons, the electron beam cannot be focused in all desired ways.

The previously mentioned lateral dimensions, both for the at least one sample space and for the examination window, can be, for example, maximum edge lengths, as long as the considered objects (sample space, examination window) are rectangular or square geometries. For round or oval geometries, a maximum diameter can be considered. For all other geometries, the dimension is understood to be a maximum extent or length.

Such object can also be solved by a loading station for receiving at least one sample cell according to one or more of the previously mentioned embodiments, wherein the loading station comprises a preparation reservoir and a sample cell holder, and wherein the preparation reservoir is arranged geodetically deeper than the sample cell holder, which is configured to receive the at least one sample cell such that a fluid contact between a subregion of the sample cell and the preparation reservoir can be established.

There is a possibility that a sample liquid or suspension can be arranged in the preparation reservoir and be absorbed into the at least one sample cell by capillary forces. This process can take place within a relatively short time frame, which is in the range of seconds or at most minutes. With the loading station, the loading of the at least one sample cell can be done without a person performing the experiment having to intervene to do this. It is thus possible without issues, such as using multiple such loading stations, to load a large number of sample cells at the same time and prepare them for the subsequent measurement. In addition, the desired sample solution or suspension can be prepared in the preparation reservoir.

According to an embodiment, the underside of the loading station can have a stand face, with which it can be placed onto an at least approximately level surface. The sample cell holder can be arranged so that it holds the at least one sample cell in relation to the preparation reservoir such that the capillary forces suck the sample liquid or suspension into the sample space against the effect of gravity.

According to further embodiments, the sample cell holder can be configured so that it receives the sample cell, for example, in an orientation so that the sample cell is oriented at least approximately perpendicular to a plane of the stand face. The orientation of the sample cell relates to the planes in which the membranes restrict the sample space extend. According to further embodiments, the sample cell holder can be configured so that at least one of the sample cells is aligned diagonally, for example at an angle between 0° and 60°, to the previously described perpendicular orientation. For example, a plane in which the membranes restricting the sample space extend can enclose an angle of 45° with the perpendicular orientation.

According to another embodiment, the loading station can be configured to receive a sample cell which can comprise a sealing element that extends between the first inner side of the first membrane and the second inner side of the second membrane in an edge region and seals off the sample space from an outer space, wherein the sealing element can leave at least one access opening free, through which the sample space can be filled. Such a loading station can comprise a sample cell holder which can be configured to receive the sample cell such that a fluid contact can be established between the access opening of the sample cell and the preparation reservoir.

For example, the sample cell holder can be configured so that it receives a sample cell with a square base area such that the sample cell can be in contact with the preparation reservoir along one of its lateral edges. If the at least one access opening of the sample cell is present on this lateral edge, the sample liquid or suspension can be absorbed into the sample space through the at least one access opening by capillary forces.

Such object can also be solved by a measuring device for examining a sample which is present in the at least one sample space of a sample cell, which is configured according to one or more of the embodiments described previously with reference to the sample cell. This measuring device can comprise a radiation source, for example an electromagnetic radiation source or an electron source, which emits a measuring beam which is aimed at a subregion of the sample cell, wherein the measuring device can further comprise a detector for detecting a measurement, such as for measuring an electron diffraction image.

As previously mentioned, the sample cell can have particular utility suitable for performing X-ray measurements or electron diffraction measurements. In the mentioned measuring device, the properties of the sample cell complement the type of measurement performed.

According to another embodiment, the measuring device can comprise a sample holder for receiving the sample cell and a processing unit which can be configured to move the sample holder such that the sample can be measured in different regions in one examination window of the sample cell in each case by the measurement beam, wherein the processing unit can be configured to move the sample holder such that the measurement beam strikes different examination windows of the sample cell one after another.

With such a measuring device, samples which are sensitive with regard to possible radiation damage caused, for example, by the electron beam used can be examined. This can relate, for example, to crystals, such as monocrystals, from organic or biological material. By performing the measurements in different examination windows, the dose of radiation can be distributed over a large sample volume.

Such object can also be solved by a method for examining a flat sample, wherein the method comprises:
a) providing a sample cell according to one or more of the previously mentioned embodiments,
b) introducing a sample solution or suspension into the at least one sample space of the sample cell,
c) introducing the sample cell, which comprises the flat sample in the at least one sample space, into a measuring device, comprising a radiation source, such as an electron source, which emits a measurement beam,
d) aligning the sample cell in relation to the measurement beam so that the beam irradiates at least a part of the sample which is present in a subregion of the sample space of the sample cell, and
e) recording a measurement, such as an electron diffraction image, of the sample.

The method for examining a flat sample can have the same or similar advantages to those which have already been previously mentioned above with respect to the sample cell, so repetitions shall be dispensed with.

According to an embodiment, in b), a crystallizable sample solution can be introduced into the sample space of the sample cell, and
the method can further comprise b1) subsequent to b), introducing the filled sample cell into a crystallization space and providing ambient conditions in the crystallization space that are favorable for crystal formation in the crystallizable sample solution.

For example, a humidity and/or a temperature and/or a pressure are set in the crystallization space as ambient conditions that are favorable for crystal formation.

The method for examining a flat crystal can be particularly efficient since flat crystals can be provided in the sample space by applying the mentioned method steps using the sample cell.

Such object can also be solved by a method for producing a flat crystal, such as a monocrystal, comprising: providing a sample cell according to one or more of the previously mentioned embodiments, introducing a crystallizable sample solution into the sample space of the sample cell, introducing the filled sample cell into a crystallization space and providing ambient conditions in the crystallization space that are favorable for crystal formation in the crystallizable sample solution, and after the crystal, such as the monocrystal, has formed in the sample space, removing the first and/or the second membrane including the corresponding retaining element and removing the crystal from the opened sample space.

With conventional means, it is often technically very complex to grow flat crystals, such as monocrystals, from a liquid. If the condition should be met at the same time that the grown crystal should meet strict requirements with regard to a homogeneous thickness, conventional methods are often technically completely unsuitable. In other words, crystals which are flat and have a constant thickness can only be grown with conventional means with a high amount of effort. These disadvantages are overcome with the mentioned method, which uses the loading station disclosed herein.

Such object can be solved by the use of a sample cell according to one or more of the previously mentioned embodiments for growing a flat crystal, such as a monocrystal, in the sample space of the sample cell. The same or similar advantages as already explained with respect to the sample cell itself apply to the use of the sample cell.

### BRIEF DESCRIPTION OF THE DRAWINGS

Further features will become evident from the description of embodiments, together with the claims and the appended drawings. Embodiments can fulfill individual features or a combination of several features.

The embodiments are described below, without restricting the general idea of the invention, based on exemplary embodiments in reference to the drawings, whereby we expressly refer to the drawings with regard to the disclosure of all details that are not explained in greater detail in the text. In the drawings:

FIG. 1 illustrates a schematically simplified cross-section through a sample cell,

FIG. 2 illustrates shows a schematically simplified plan view of a sample cell,

FIG. 3 illustrates a schematically simplified detailed view of the sample cell shown in the plan view in FIG. 2,

FIG. 4 illustrates a schematically simplified perspective diagram of a loading station for receiving a sample cell,

FIG. 5 illustrates a schematically simplified side view of a loading station with a sample cell inserted, and

FIG. 6 illustrates a measuring device for examining a sample which is present in the sample space of a sample cell in a very simplified and schematic diagram.

In the drawings, the same or similar elements and/or parts are, in each case, provided with the same reference numerals such that they are not introduced again in each case.

### DETAILED DESCRIPTION

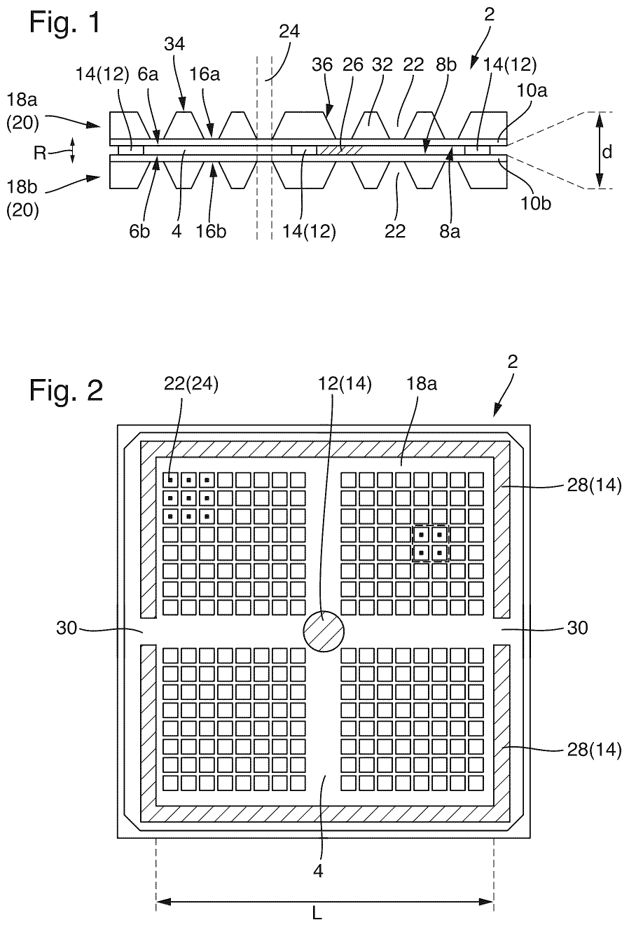

FIG. 1 shows a schematically simplified section view of a sample cell 2 which comprises a flat sample space 4. In the diagram from FIG. 1, the sample cell 2 comprises, by way of example, a single sample space 4. According to further exemplary embodiments not shown in the figures, the sample cell 2 comprises more than one single sample space 4. In the context of the following description, reference is made to a sample cell 2 which has a single sample space 4 simply by way of example. The flat sample space 4 is restricted on its first large flat side 6a by a first inner side 8a of a first membrane 10a. On its second large flat side 6b, the sample space 4 is restricted by a second inner side 8b of a second membrane 10b. A spacer 12 extends between the first inner side 8a and the second inner side 8b, which spacer is built from multiple spacing elements 14 in the exemplary embodiment shown. In other words, the spacing elements 14 together form the spacer 12. The spacer 12 defines a distance d between the first membrane 10a and the second membrane 10b.

A first retaining element 18a is arranged on a first outer side 16a, which faces away from the sample space 4, of the first membrane 10a. A second retaining element 18b is arranged on a second outer side 16b, which also faces away from the sample space 4, of the second membrane 10b. The first retaining element 18a and the second retaining element 18b together form a retaining structure 20 of the sample cell 2. This retaining structure 20 is configured, for example, so that the sample cell 2 is inherently stable.

The first retaining element 18a and the second retaining element 18b each comprise a plurality of apertures 22. For reasons of simplicity, only one aperture 22 in each retaining element 18a, 18b is provided with a reference sign. The apertures 22 of the first and second retaining elements 18a, 18b are arranged to align with each other in a direction R transverse to the flat sides 6a, 6b. This results in a plurality of examination windows 24, in which the outer sides 16a, 16b of the membranes 10a, 10b are exposed.

In the region of the examination window 24, the sample cell 2 can be easily irradiated. This serves to examine a sample 26, which is present in the sample space 4 and only indicated in regions by hatching and which is, for example, a crystal, further, for example, a monocrystal. The sample cell 2 has particular utility for the examination of the sample 26 by electron diffractometry. The sample cell 2 is also suitable for examining the sample 26 by electromagnetic radiation, for example X-rays. In the region of the examination windows 24, the sample 26 is separated from the outer space only by the membranes 10a, 10b. For the membranes 10a, 10b, a material is selected that is largely transparent for the electromagnetic radiation used or respectively electron-transparent. If the measurement is performed by electron radiation, graphene, boron nitride, or the like, for example, are suitable as the material for the membranes 10a, 10b. The sample cell 2 has a plurality of examination windows 24. This has particular utility for an examination of the sample 26 with a high dose of radiation. The dose of radiation can be distributed over a large sample volume in that individual examination windows 24 are irradiated, for example, temporally one after another and the sample 26 is measured in this region. Radiation damage to the sample 26 can be reduced in this way.

Examinations by electron diffractometry take place in many cases under vacuum conditions. But not every sample 26 can be readily exposed to a vacuum. For this reason, the sample cell 2 according to one exemplary embodiment is configured to be vacuum-tight. To achieve this, the first inner side 8a of the first membrane 10a is connected in a firmly bonded manner to the spacer 12, at least to a part of the spacing elements 14 forming the spacer 12. The second inner side 8b of the second membrane 10b is also connected in a firmly bonded manner to the spacer 12, at least to a part of the spacing elements 14 forming the spacer 12. To improve the stability of the sample cell 2, the first outer side 16a of the first membrane 10a can also be connected in a firmly bonded manner to the first retaining element 18a. This also applies to the second retaining element 18b, which can be connected in a firmly bonded manner to the second outer side 16b of the second membrane 10b. A firmly bonded connection is achieved, for example, by applying a suitable pressure to the involved elements. The firmly bonded connection can take place without auxiliary substances or using one or more auxiliary substances. An auxiliary substance-free connection takes place, for example, by at least low interdiffusion of the materials into each other or by form-fitting adaptation at the microscopic level. Auxiliary substances that are suitable for producing a firmly bonded connection are, for example, vacuum-resistant adhesives, such as epoxy resins or the like.

FIG. 2 shows a schematically simplified plan view of a sample cell 2 according to another exemplary embodiment. The sample cell 2 comprises a sealing element 28, which is configured in two pieces and fulfills the function of a spacing element 14. Another spacing element 14 is arranged centrally in the sample space 4. This is surrounded by the sealing element 28. The sealing element 28 extends, just like it is shown in FIG. 1 for the spacing elements 14, between the first inner side 8a of the first membrane 10a and the second inner side 8b of the second membrane 10b. The sealing element 28 is arranged in an edge region of the sample cell 2 and seals off the sample space 4 from the outer space. In the exemplary embodiment shown, the sealing element 28 leaves the access openings 30 free, through which the sample space 4 can be filled.

In the plan view from FIG. 2, only the first retaining element 18a is visible. It is shown partially transparently with respect to the sealing element 28 and the central spacing element 14 which are below it. The apertures 22, which expose the examination windows 24, are located in the first retaining element 18a, arranged in a regular grid. The apertures 22 are indicated with dots in the subregions of the first retaining element 18a. The access openings 30 of the sealing element 28 can be closed in a vacuum-tight manner. For this purpose, the access opening 30 is closed, for example, with a vacuum-resistant adhesive or another suitable sealant.

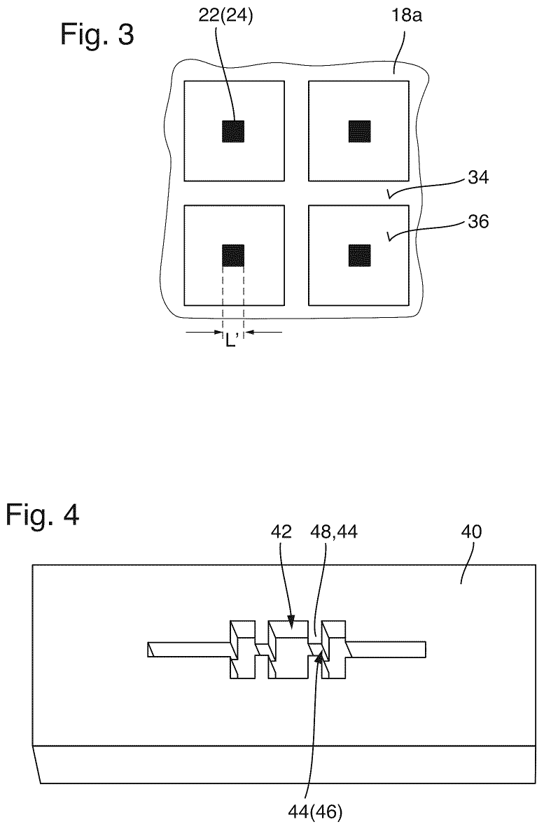

The detailed view shown in FIG. 3 in turn shows a plan view of the first retaining element 18a. This is built from webs 32 (cf. also FIG. 1), toward the upper end face 34 of which the view is directed in FIG. 3. The first retaining element 18a is produced, for example, from silicon. The apertures 22, of which only a single one is provided with a reference sign in FIG. 3, are produced, for example, by photolithography. Due to this production method, the typical structure of the webs 32, which is trapezoidal in cross-section, shown in FIG. 1 results. The flanks 36 of the webs 32 are shown in FIG. 3 with dotted shading.

The sample cell 2 according to the exemplary embodiments shown is provided with spacers or respectively spacing elements 14 which, viewed in a direction R transverse to the large flat sides 6a, 6b of the sample space 4, have an at least approximately identical material thickness. In other words, all of the spacing elements 14 forming the spacers 12 (the same also applies to the sealing element 28, if this forms part of the spacer 12) are configured with a constant identical material thickness. The spacer 12 defines the distance d between the inner sides 8a, 8b of the membranes 10a, 10b and thus a thickness of the sample 26, which is, for example, a crystal, further, for example, a monocrystal. The constant material thickness of the spacing elements 14 leads to the inner sides 8a, 8b of the membranes 10a, 10b being arranged at least approximately plane-parallel to each other. This in turn leads to a crystal present in the sample space 4 growing flat and having a very homogeneous thickness.

To provide a crystal, such as a monocrystal, as a sample 26 in the sample space 4, a crystallizable solution, for example, is introduced into the sample space 4 through the access openings 30. The crystallizable solution crystallizes within the sample space 4, for example, to form a monocrystal, which can then be examined by X-ray diffractometry.

A sample cell 2 according to further exemplary embodiments comprises a sample space 4, the aspect ratio of which between a lateral extent L, measured in a direction at least approximately parallel to the large flat sides 6a, 6b, and thickness that corresponds to the distance d of the membranes 10a, 10b, meaning is measured in the direction R at least approximately perpendicular to the large flat sides 6a, 6b, is in a ratio of at least 10:1. In other words, the sample space 4 is at least ten times as large in the lateral direction as in the direction perpendicular thereto in which it is irradiated. In a sample cell 2 which comprises, as shown in FIG. 2 by way of example, a square sample space 4, the lateral extent L is measured as an edge length.

The sample space 4 has a lateral extent L which is between 100 μm and 100 mm. A thickness of the sample space 4 is between 1 nm and 10 μm. The examination windows 24 have a lateral dimension L′, which is measured just like the lateral extent L of the sample space 4, which is between 50 μm and 200 μm in a direction at least approximately parallel to the large flat sides 6a, 6b. The lateral dimension L′ of the examination windows 24 is also measured as an edge length, if they are, as in the exemplary embodiment in FIG. 3, square examination windows 24 by way of example. Otherwise, what has been said regarding the dimension of the sample space 4 applies.

FIG. 4 shows a schematically simplified perspective diagram of a loading station 40 which is configured to receive at least one sample cell 2 according to one or more of the previously mentioned exemplary embodiments. The loading station 40 comprises a preparation reservoir 42, which is provided as a recess in the loading station 40, which is configured as a block. The walls of the preparation reservoir 42 form a sample cell holder 44 in portions. For example, the lateral end faces 46 of the projections 48 form the sample cell holder 44 in the exemplary embodiment shown in FIG. 4. The preparation reservoir 42 is arranged geodetically deeper than the sample cell holder 44. The sample cell holder 44 is also configured to receive the sample cell 2 such that a fluid contact can be established between a subregion of the sample cell 2 and the preparation reservoir 42.

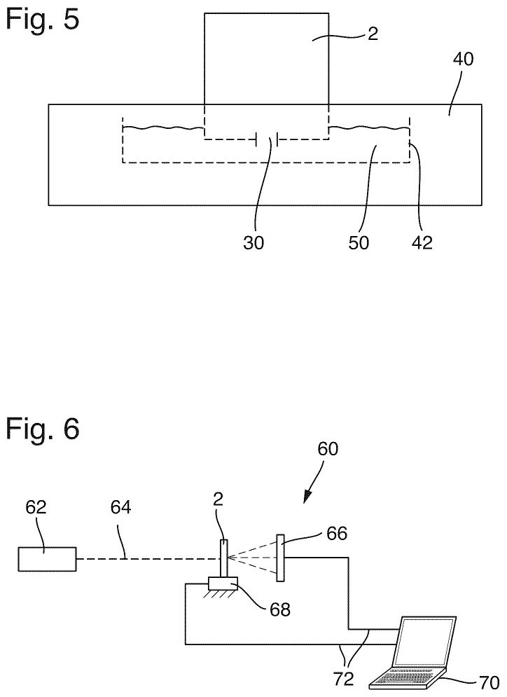

FIG. 5 shows a very schematically simplified side view of the loading station 40 with a sample cell 2 placed therein. By way of example, a sample solution 50 or a suspension, such as a crystallizable sample solution 50 or suspension, is located in the preparation reservoir 42. It is also provided that the sample solution 50 or suspension is produced directly in the preparation reservoir 42. The sample cell holder 44 is configured to receive the sample cell 2 such that a fluid contact can be established between its access opening 30 and the preparation reservoir 42, or respectively the sample solution 50 present in the preparation reservoir 42. For this purpose, the sample cell 2 is submerged into the preparation reservoir 42 until the access opening 30 of the sample cell 2 is in fluid contact with the sample solution 50.

The sample solution 50 is sucked into the sample space 4 against the effect of gravity by capillary forces. After the sample cell 2 is loaded, the access opening 30 can be closed. If an examination of the sample 26 takes place immediately, it is not necessary to hold the sample 26 stable over a longer time and the access opening 30 does not have to be closed.

FIG. 6 shows a very schematically simplified diagram of a measuring device 60 for examining a sample 26 which is present in the sample space 4 of a sample cell 2 according to an exemplary embodiment. The measuring device 60 comprises a radiation source 62, which emits a measurement beam 64. The radiation source 62 is, for example, an electromagnetic radiation source, such as an X-ray source, or also an electron beam radiation source. The measurement beam 64 is aimed at a subregion of the sample cell 2 and strikes it in the region of an examination window 24. The measuring device 60 also comprises a detector 66, which is configured to detect measurement data, such as to detect an electron diffraction image or an X-ray diffraction image. To examine various examination windows 24 of the sample cell 2, the sample cell is arranged on a movable sample holder 68, for example a positioning table.

X-ray and electron detectors for measuring a diffraction image are well-known in the art. However, by way of example, the detector 66 can be a solid state detector that uses semiconductors to detect x-rays or electrons. There are direct digital detectors, so-called because they directly convert x-ray photons to electrical charge and thus a digital image. The detection of electrons directly provides an electrical charge and thereby the digital image. Furthermore, there are indirect systems that may have intervening steps. For example, first converting x-ray photons to visible light, and then an electronic signal. Both systems typically use thin film transistors to read out and convert the electronic signal to a digital image. The most simple and traditional detector is the chemical film, in which the silver-containing grains are directly affected by the x-rays and electrons, respectively.

The measuring device 60 also comprises a processing unit (e.g., processor, controller, CPU, PC computer etc.) 70, which is configured to move the sample holder 68 such that the sample 26, which is located within the sample space 4 of the sample cell 2, is measured at different regions in one examination window 24 of the sample cell 2 in each case by the measurement beam 64. The processing unit 70 can be configured to move the sample holder 68 such that the measurement beam 64 strikes different examination windows 24 of the sample cell 2 one after another. For this purpose, the processing unit 70, which also serves to read out the detector 66, is connected to the aforementioned units via suitable data connections 72. According to one exemplary embodiment, a method for examining a flat crystal which is present, for example, as a sample 26 in the sample space 4 of the sample cell 2 comprises the following.

First, a sample cell 2 according to an exemplary embodiment is provided. A crystallizable sample solution 50, a suspension, for example a liquid with crystals or crystallites contained therein or a sample present in liquid form in another way is introduced into the sample space 4 of the sample cell 2; this takes place, for example, using the loading station 40. If a crystallizable liquid is introduced into the sample cell 2, the filled sample cell 2 is subjected in a crystallization space to ambient conditions that are favorable for crystal formation of the crystallizable sample solution 50. Ambient conditions that are favorable for the crystallization process are, for example, certain temperatures or certain humidities. It is also provided that the sample cell 2 is only subjected to the usual ambient conditions/laboratory conditions if these are sufficient for crystal formation. In this case, the laboratory space corresponds to the crystallization space. Then the sample cell 2, which now comprises at least one crystal, for example a monocrystal, in its sample space 4, is introduced into a measuring device 60, which comprises a radiation source 62 that emits a measurement beam 64. As already previously explained multiple times, the radiation source 62 is, for example, an X-ray source or an electron radiation source. The sample cell 2 is aligned in relation to the measurement beam 64; this takes place, for example, using the sample holder 68. The alignment takes place such that one subregion of the sample cell 2 is irradiated in each case and an electron diffraction image, for example, can be recorded using a detector 66. The sample cell 2 is irradiated in the region of its examination windows 24.

According to one exemplary embodiment, a method for producing a flat crystal, such as a monocrystal, which can also be examined in a measuring device 60, as shown schematically simplified in FIG. 6, but also in another suitable measuring device, comprises the following.

Again, a sample cell 2 according to an exemplary embodiment is first provided. A crystallizable sample solution 50 is again introduced into the sample space 4 of the sample cell 2. The filled sample cell 2 is again held for a sufficient period of time in a crystallization space under ambient conditions that are favorable for crystal formation of the crystallizable sample solution 50. After a crystal, for example a monocrystal, has formed in the sample space 4 of the sample cell 2, the first membrane 10a including the first retaining element 18a and/or the second membrane 10b including the second retaining element 18b is removed. In this way, the sample space 4 is opened. The crystal, for example a monocrystal, present in the sample space 4 can be examined in the half-opened sample cell 2. It is also provided to remove the monocrystal present in the sample space 4 and supply it to a measurement. It is also provided to examine the crystal, held only by the sealing element 28, for example in transmission, after removing the membranes 10a, 10b on both sides including the retaining elements 18a, 18b.

The sample cell 2 can thus be used to grow a flat crystal, such as a monocrystal, in the sample space 4.

While there has been shown and described what is considered to be embodiments of the invention, it will, of course, be understood that various modifications and changes in form or detail could readily be made without departing from the spirit of the invention. It is therefore intended that the invention be not limited to the exact forms described and illustrated, but should be constructed to cover all modifications that may fall within the scope of the appended claims.

### LIST OF REFERENCE SIGNS

2 Sample cell
4 Sample space
6a First large flat side
6b Second large flat side
8a First inner side
8b Second inner side
10a First membrane
10b Second membrane
12 Spacer
14 Spacing element
16a First outer side
16b Second outer side
18a First retaining element
18b Second retaining element
20 Retaining structure
22 Aperture
24 Examination window
26 Sample
28 Sealing element
30 Access opening
32 Web
34 End faces
36 Flanks
40 Loading station
42 Preparation reservoir
44 Sample cell holder
46 Lateral end faces
48 Projections
50 Sample solution
60 Measuring device
62 Radiation source
64 Measurement beam
66 Detector
68 Sample holder
70 Processing unit
72 Data connections
d Distance
L Lateral extent
L′ Lateral dimension
R Direction

What is claimed is:

1. A method for producing a flat crystal, comprising:
providing a sample cell comprising:
at least one sample space, which is restricted on its first flat side by a first inner side of a first membrane and on its second flat side by a second inner side of a second membrane,
a spacer arranged between the first and the second inner sides, the spacer establishing a distance between the first and second membranes,
a first retaining element arranged on a first outer side, which faces away from the at least one sample space of the first membrane, and
a second retaining element arranged on a second outer side, which faces away from the at least one sample space of the second membrane,
wherein the first and second retaining elements together form a retaining structure,
the first and second retaining elements each have a plurality of apertures which are arranged to align with each other in a direction transverse to the first and second flat sides so that a plurality of examination windows are formed, in which the first and second outer sides of the first and second membranes are exposed,
introducing a crystallizable sample solution into the at least one sample space of the sample cell,
introducing the filled sample cell into a crystallization space and providing ambient conditions in the crystallization space that are favorable for crystal formation in the crystallizable sample solution,
after the crystal has formed in the sample space, removing one or more of the first and the second membranes and a corresponding one of the first and second retaining elements, and
removing the crystal from the opened sample space.

2. The method according to claim 1, wherein the flat crystal is a monocrystal.

3. The method according to claim 1, wherein one or more of the first inner side of the first membrane is connected to the spacer, the first outer side of the first membrane is connected to the first retaining element, the second inner side of the second membrane is connected to the spacer, and the second outer side of the second membrane is connected to the second retaining element in a firmly bonded manner.

4. The method according to claim 1, wherein the firmly bonded manner is vacuum-tight.

5. The method according to claim 1, further comprising a seal, which extends between the first inner side of the first membrane and the second inner side of the second membrane, in an edge region and seals off the at least one sample space from an outer space, wherein the seal comprises at least one access opening, through which the at least one sample space can be filled.

6. The method according to claim 1, wherein the spacer, when viewed in a direction transverse to the first and second flat sides, has a constant material thickness so that the first and second inner sides of the first and second membranes are arranged at least approximately plane-parallel to each other.

7. The method according to claim 1, wherein the at least one sample space has an aspect ratio between a lateral extent, measured in a direction at least approximately parallel to the first and second flat sides, and a thickness, measured in the direction at least approximately perpendicular to the first and second flat sides, of ten to one or greater.

8. The method according to claim 1, wherein the at least one sample space has lateral extents, measured in a direction at least approximately parallel to the first and second flat sides, between 100 μm and 100 mm and the at least one sample space has a thickness, measured in the direction at least approximately perpendicular to the first and second flat sides, between 1 nm and 10 μm.

9. The method according to claim 1, wherein the plurality of examination windows have a lateral dimension, viewed in a direction at least approximately parallel to the first and second flat sides, which is between 10 μm and 200 μm.
